(19) United States
(12) Patent Application Publication
(10) Pub. No.: US 2006/0081939 A1
(43) Pub. Date: Apr. 20, 2006

(54) Semiconductor device having misfet using high dielectric constant gate insulation film and method for fabricating the same

(76) Inventors: Yasushi Akasaka, Ibaraki (JP); Kazuhiro Miyagawa, Gifu (JP); Takaoki Sasaki, Yamagata (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/222,139

(22) Filed: Sep. 9, 2005

(30) Foreign Application Priority Data
Dec. 8, 2004 (JP) 2004-354791
Sep. 10, 2004 (JP) 2004-263784

(51) Int. Cl. H01L 29/76

(52) U.S. Cl. 257/371

(57) ABSTRACT

A semiconductor device having a metal insulator semiconductor field effect transistor (MISFET) with increased electron mobility and enhanced hole mobility is disclosed. In this semiconductor device, a p-type well layer and an n-type well layer are formed in a surface portion of a silicon substrate. A nitrogen-nondoped n-channel interface layer and a nitrogen-free n-channel high dielectric constant gate insulation film plus an n-channel gate electrode are formed in an n-channel MISFET as partitioned by an element isolation region. And, n-type source/drain diffusion layers are provided. In a p-channel MISFET, a nitrogen-doped p-channel interface layer, a nitrogen-added p-channel high dielectric gate insulation film and a p-channel gate electrode are formed along with p-channel source/drain diffusion layers as provided therein. A method of fabricating this semiconductor device is also disclosed.

### CROSS-REFERENCE TO RELATED APPLICATIONS

This application is based on and claims priority of Japanese Patent Application (JPA) No. 2004-263784, filed on Sep. 10, 2004 and also JPA No. 2004-354791, filed Dec. 8, 2004, the entire contents of which are incorporated herein by reference.

### FIELD OF THE INVENTION

The present invention relates generally to semiconductor devices having metal insulator semiconductor field effect transistors (MISFETs) using a high dielectric constant gate insulating film and methodology of making the same. More particularly but not exclusively, this invention relates to a semiconductor device having n-channel and p-channel MISFETs with a high dielectric constant (high-k) film applied as a gate insulation film used for insulated-gate FETs (MISFETs) and a fabrication method thereof.

### DESCRIPTION OF RELATED ART

In recent years, diligent efforts are made to achieve further miniaturization and higher integration of semiconductor devices, in particular, MISFETs. In viewpoints of drive current guaranty and power consumption decrease, it is required to make gate insulation films thinner. From requirements of scaling rules, a need is felt to design silicon dioxide (SiO₂) films, which have widely been used as gate insulator films, to have a thickness of 2 nanometers (nm) or less. Unfortunately, using such ultrathin SiO₂ film as a gate insulator film results in a gate leakage current due to “tunnel” currents reaching a non-negligible value with respect to source/drain currents. This poses a serious problem that impedes accomplishment of both increased current driving ability or “drivability” and reduced power consumption.

Consequently, in order to lower the MISFET gate leakage current, there has been studied in various ways the methodology that uses for the gate insulator film a chosen insulative material that is greater in dielectric constant, k, than SiO₂ films, which is known as high dielectric constant (high-k) material. Typical Examples of this high-k film material are metal oxides such as hafnia (HfO₂) and zirconia (ZrO₂), metal silicates such as hafnium silicate (HfSiOₓ) and zirconium silicate (ZrSiOₓ), metal alminates such as hafnium alminate (HfAlOₓ) and zirconium alminate (ZrAlOₓ), and lanthanoid oxides such as La₂O₃, Y₂O₃ or else. Especially, certain films which are made of hafnium (Hf)-containing material such as HfO₂, HfSiOₓ or HfAlOₓ and oxynitrides thereof are relatively excellent in thermal stability. Thus it is considered that these films are readily introduced into currently available large scale integration (LSI) fabrication processes. A high dielectric constant film made of the above-noted high-k material has its dielectricity of more than ten (10), which is greater than SiO₂ film's dielectricity of 3.9. This makes it possible to enlarge a physical film thickness while at the same time maintaining an effective gate insulation film thickness (electrically translated film thickness to that of SiO₂ film, also known as the equivalent oxide thickness or “EOT”) at a small value. It is also possible to suppress the above-stated gate leakage current occurring due to tunnel currents, thereby enabling reduction of electrical power consumed.

Additionally, in the case of using the EOT-reduced gate insulator film, when using a polycrystalline silicon or “poly-silicon” layer for the gate electrode, a problem takes place as to the so-called depletion—that is, a depleted layer can be formed in a polysilicon layer region with a contact between the gate electrode and the gate insulator film. This depletion badly behaves to increase the effective thickness of the gate insulator film. To avoid this depletion problem, an approach to forming the gate electrode by metals is under consideration.

One prior art technique is disclosed, for example, in “2002 International Electron Devices Meeting Technical Digest,” p. 355, 2002. This technique is such that the above-noted high-k material is applied to the gate insulation film of a MISFET as will be explained with reference to FIG. 13 below. FIG. 13 is a cross-sectional diagram of a device structure including a pair of n- and p-channel MISFETs each having a gate electrode of the so-called damascene structure, which is fabricated by a process for forming MISFET source/drain diffusion layers and thereafter forming its gate electrode as buried in an opening of an interlayer dielectric (ILD) film.

As shown in FIG. 13, a p-type well layer 102 and an n-well layer 103 are formed in the surface of a silicon substrate 101. An element isolation region 104 is formed by known shallow trench isolation (STI) so that active regions of n- and p-channel MISFETs are partitioned.

In the active region of n-channel MISFET, a pair of opposing extension layers 105 of n conductivity type and source/drain diffusion layers 106 of the same conductivity type are formed so that each extension layer is connected to its corresponding source/drain diffusion. At upper part thereof, a pair of gate side-walls 107 comprised of silicon nitride films for example are formed so that these laterally oppose each other. In a groove defined by this pair of opposite gate sidewalls 107, a multilayer structure is formed, including a high dielectric gate insulation film 108 of high dielectric constant (high-k) which is made of a high-k material such as for example HfO₂, a conductive barrier film 109 made for example of titanium nitride (TiN), and a low resistivity metal film 110 made for example of tungsten (W), which are stacked or laminated in sequence. The barrier film 109 and a low resistivity metal film 110 constitute a gate electrode 111 of n-channel MISFET having the metal gate electrode structure.

Similarly, in the active region of the p-channel MISFET, a pair of opposing extension layers 112 of p conductivity type and source/drain diffusion layers 113 of the same conductivity type are formed so that respective corresponding layers are coupled together. A pair of overlying gate sidewalls 114 made for example of silicon nitride are formed to oppose each other. In a groove defined by this pair of gate sidewalls 114, a multilayer structure of high dielectric gate insulator film 108 and conductive barrier film 109 plus a low resistivity metal film 110 is formed. Here, the barrier film 109 and a low resistivity metal film 110 make up a p-channel MISFET gate electrode 115 of the metal structure.

A contact etch stopper layer 116 formed of a silicon nitride film and an ILD film 117 made of silicon oxide, for example, are formed so that these are multilayered to cover or coat an almost entire surface of the device. The contact etch stopper layer 116 functions as an etching stopper during formation of contact holes (not shown) in the source/drain diffusion layers 106 and 113.

However, in the prior art MISFET device having the aforesaid high dielectric gate insulation film (high-k gate insulator film), charge carriers such as electrons or holes decrease in mobility. In particular, electron mobility is noticeably reduced. This will be explained with reference to FIGS. 14-15.

FIG. 14 is a graph showing the electron mobility in an n-channel MISFET fabricated by the prior art method stated above; FIG. 15 is a graph showing the hole mobility of a p-channel MISFET. In these graphs, the effective gate field intensity is plotted in a lateral axis of coordinate, while the surface mobility of carrier charge is indicated in vertical axis. As shown in FIG. 14, the use of the high-k gate insulator film results in an appreciable decrease in electron mobility. While a corresponding curve of a MISFET having its gate insulator film formed of an ultrathin SiO₂ film with a thickness of 3 nm is shown as a comparative example, the electron mobility of high-k gate insulator film is as small as about one-half of that of this comparative example. When compared to the so-called universal curve (i.e., all-inclusive curve that provides effective gate field dependency of the mobility) which is obtained by SiO₂ films having a thickness determined to the extent that electrons do not tunnel directly, the electron mobility decreases significantly. Additionally as shown in FIG. 15, the hole mobility also decreases in a similar way to the electron mobility although its degree is less when compared thereto. In FIG. 15, a curve of a MISFET having an ultrathin SiO₂ gate insulator film of 3 nm thick is shown for comparison purposes. It can also be seen that its mobility decreases as a whole in comparison with the universal curve of the hole mobility.

In the MISFET with the high-k gate insulator film, an interface between the silicon substrate surface and the high-k gate insulator film is higher in interface state density than an interface between silicon substrate surface and SiO₂ gate insulator film. In addition, carrier charge is readily capturable into the gate insulator film. Increased positive and negative charges in high-k gate insulator film cause Coulomb scattering of the carrier charge in a channel. Due to these phenomena, the carrier charge becomes less in surface mobility. Especially, a decrease in electron mobility is significant. A result of such decrease in carrier mobility is that it becomes difficult to sufficiently enhance the drivability of the MISFET having the high-k gate insulator film. This makes it difficult to achieve higher performances, including higher speeds and lower power consumption, of a semiconductor device made up of n- and p-channel MISFETs of the type stated above. However, no control schemes are known until today for increasing both the electron mobility and the hole mobility in the n- and p-channel MISFETs (i.e., complementary MISFET).

Additionally, in the approach to attaining higher performances of the complementary MISFET having the high-k gate insulator film and using metal gate electrodes as in the gate damascene structure, in order to achieve a high drive current in the turn-on (conductive) state of MISFET and also a low leakage current in the turn-off (nonconductive) state thereof, it is inevitable to lower the absolute value of a threshold voltage in each MISFET.

To do this, it is desired to choose for each MISFET an appropriate metallic material which exhibits an enlarged difference in Fermi level between MISFET gate electrode and semiconductor surface. However, those metals which are less in work function (Fermi level is near the end of a conduction band of Si) and which are adaptable for use in n-channel MISFETs with the semiconductor surface designed to have the p conductivity type are typically high in reactivity, resulting in a decrease in insulating properties of high-k gate insulator film. Thus it has been hardly possible to avoid the risk of unwanted increases in leakage currents in gate insulator films.

### SUMMARY OF THE INVENTION

In accordance with a first aspect of the invention relating to the semiconductor device, a semiconductor device is provided which includes a p-channel MISFET and an n-channel MISFET each having a gate insulation film and a metal gate electrode on or above a semiconductor substrate. The gate insulation film is formed using a high dielectric constant film that is higher in dielectricity than silicon oxide films. The amount of nitrogen atoms contained in either the gate insulation film of the p-channel MISFET or a portion of its metal gate electrode which is in contact with a surface of the gate insulation film is greater than the amount of nitrogen atoms contained in either the gate insulation film of the n-channel MISFET or a portion of the metal gate electrode thereof as contacted with a surface of the gate insulation film.

In accordance with a second aspect of the invention relating to the semiconductor device, a semiconductor device is provided which includes a p-channel MISFET and an n-channel MISFET each having a gate insulation film and a metal gate electrode above a semiconductive substrate. The gate insulation film is formed using a high dielectric constant film high in dielectricity than silicon oxide films. The metal gate electrode at a portion in contact with a surface of the gate insulation film of the n-channel MISFET is made of a metal silicide with its silicon amount greater than a stoichiometric composition ratio.

In accordance with a first aspect of the invention concerning semiconductor device fabrication methodology, there is provided a method for making a semiconductor device including a p-channel MISFET and an n-channel MISFET each having a gate insulation film and a metal gate electrode on or above a semiconductive substrate, wherein the gate insulation film is formed using a high dielectric constant film higher in dielectricity than silicon oxide films. The method includes forming a high dielectric constant film above the substrate. Then, form a first conductive film above the high dielectric constant film. Then, expose the high dielectric constant film by removing a portion of the first conductive film in a region in which the p-channel MISFET is to be formed while leaving another portion of the first conductive film in a region used for formation of the n-channel MISFET. Next, form a second conductive film to cover an exposed portion of the high dielectric constant film. The second high dielectric constant film is specifically arranged to contain therein nitrogen atoms greater in amount than those of the first conductive film. The first conductive film is for use as part of the metal gate electrode of the n-channel MISFET, while the second conductive film is for use as part of the metal gate electrode of the p-channel MISFET.

In accordance with a second aspect of the invention regarding the semiconductor device fabrication methodology, a method is provided for making a semiconductor device having a p-channel MISFET and an n-channel MISFET each having a gate insulation film and a metal gate electrode above a semiconductive substrate. The gate insulation film is formed using a high dielectric constant film high in dielectricity than a silicon oxide film. The method includes forming a high dielectric constant film above the substrate, forming a first conductive film above the high dielectric constant film, and exposing the high dielectric constant film by removing a portion of the first conductive film in a region in which the p-channel MISFET is to be formed while leaving another portion of the first conductive film in a region used for formation of the n-channel MISFET. Then, apply nitridation to the exposed part of the high dielectric constant film by plasma nitridation techniques. Next, form a second conductive film to cover the high dielectric constant film thus nitrided. The first conductive film is for use as part of the metal gate electrode of the n-channel MISFET. The second conductive film is for use as part of the metal gate electrode of the p-channel MISFET.

In accordance with a third aspect of the invention as to semiconductor device fabrication methodology, a method is provided for making a semiconductor device including a p-channel MISFET and an n-channel MISFET each having a gate insulation film and a metal gate electrode above a semiconductive substrate, wherein the gate insulation film is formed using a high dielectric constant film high in dielectricity than a silicon oxide film. The method includes forming a high dielectric constant film above the semiconductive substrate, forming above the high dielectric constant film a second conductive film containing nitrogen therein, exposing the high dielectric constant film by removing a portion of the second conductive film in a region in which the n-channel MISFET is to be formed while leaving another portion of the second conductive film in a region used for formation of the p-channel MISFET, and forming a first conductive film to cover the exposed part of the high dielectric constant film. The first conductive film is less in nitrogen content than the second conductive film. The first conductive film is for use as part of the metal gate electrode of the n-channel MISFET. The second conductive film is for use as part of the metal gate electrode of the p-channel MISFET.

In accordance with a fourth aspect of the invention as to semiconductor device fabrication methodology, a method is provided for making a semiconductor device including a p-channel MISFET and an n-channel MISFET each having a gate insulation film and a metal gate electrode above a semiconductive substrate, wherein the gate insulation film is formed using a high dielectric constant film high in dielectricity than a silicon oxide film. The metal gate electrode at a portion in contact with a surface of the gate insulation film of the n-channel MISFET is made of a metal silicide with its silicon amount greater than a stoichiometric composition ratio. The high dielectric constant film is made of at least one kind of high dielectric constant film material as selected from the group consisting of HfO₂, ZrO₂, HfSiOₓ, ZrSiOₓ, HfAlOₓ, ZrAlOₓ, Y₂O₃, and La₂O₃.

### BRIEF DESCRIPTION OF THE DRAWINGS

FIG. 1 is a diagram showing in cross-section a complementary MISFET device in accordance with an embodiment 1 of this invention.

FIG. 2 is a diagram graphically showing the composition of a high dielectric gate insulation film of the MISFET in accordance with the embodiment 1 of the invention.

FIG. 3 is a graph showing the composition of a high dielectric gate insulation film of the MISFET in accordance with the embodiment 1 of the invention.

FIG. 4 is a graph showing a relation of electron mobility versus effective gate field intensity, for demonstration of technical effects of the embodiment 1 of the invention.

FIG. 5 is a graph showing a plot of hole mobility versus effective gate field intensity for explanation of effects of the embodiment 1.

FIG. 6 is a graph showing a plot of electron mobility vs. effective gate field intensity for explanation of effects of the embodiment 1.

FIG. 7 is a graph showing a plot of hole mobility vs. effective gate field intensity for explanation of effects of the embodiment 1.

FIG. 8 is a graph showing flat-band voltages for explanation of effects of the embodiment 1.

FIG. 9 is a graph showing a leakage current of high dielectric gate insulator film for explanation of effects of the embodiment 1.

FIG. 10 depicts a cross-sectional view of a complementary MISFET device in accordance with an embodiment 2 of the invention.

FIGS. 11A through 11J illustrate, in cross-section, device structures at major process steps of a fabrication method of the MISFET in accordance with the embodiment 2.

FIG. 12 is a cross-sectional view of a MISFET in accordance with a modification of the embodiment 2 of the invention.

FIG. 13 is a sectional view of one prior known MISFET device.

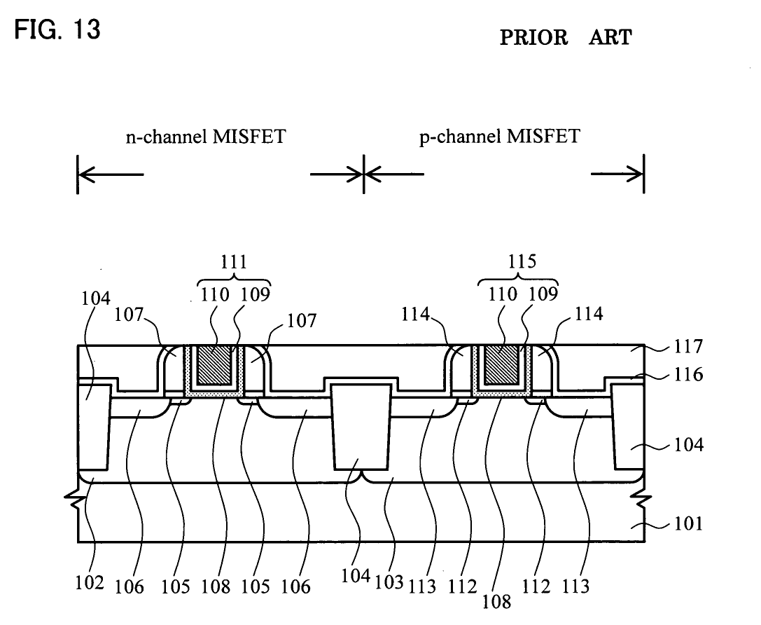

FIG. 14 is a graph showing plots of electron mobility for explanation of problems faced with the prior known device.

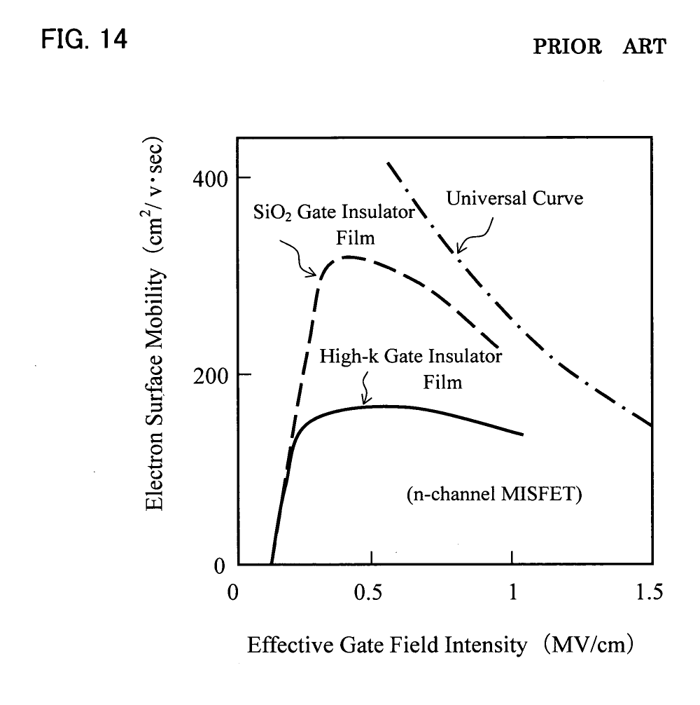

FIG. 15 is a graph showing plots of hole mobility for explanation of problems in the prior art.

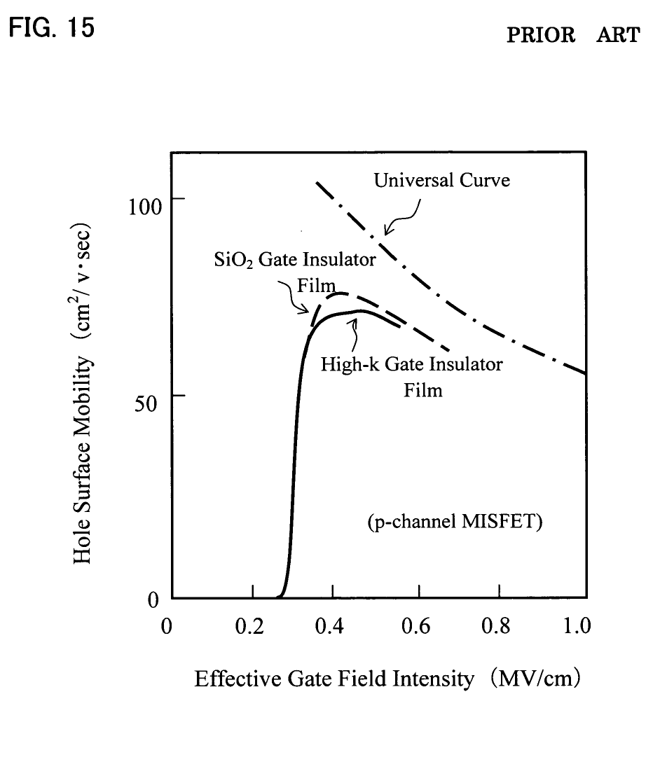

### DETAILED DESCRIPTION OF THE INVENTION

The inventors as named herein found that when letting nitrogen atoms be contained in either a gate insulation film formed using a high-k film or a metal gate electrode, the n-channel MISFET decreases in electron mobility while adversely permitting the p-channel MISFET to improve in hole mobility. The present invention was mainly made on the basis of this discovery.

Several embodiments of the present invention will be explained in detail with reference to the accompanying drawings below.

### Embodiment 1

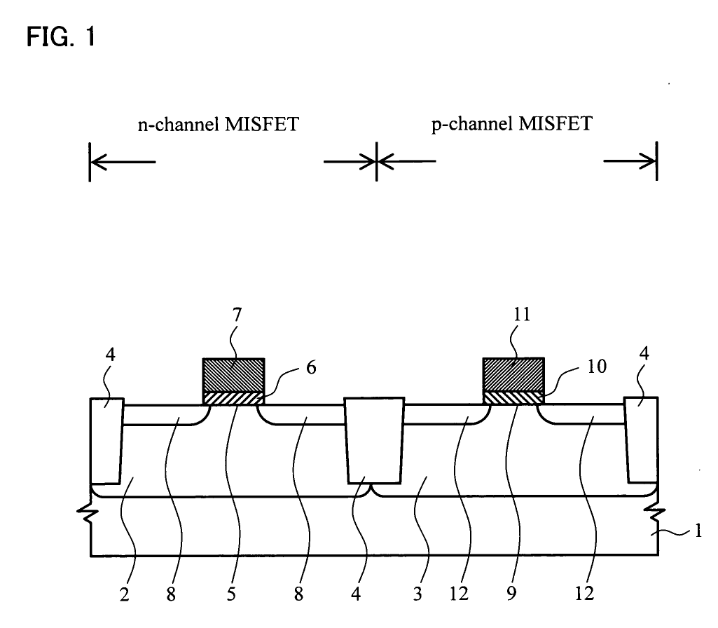

Referring to FIG. 1, there is shown a cross-sectional view of a complementary metal insulator semiconductor field effect transistor (MISFET) device having an n-channel MISFET and a p-channel MISFET in accordance with an embodiment 1 of this invention, wherein each MISFET has a high dielectric material gate insulation film and a gate electrode of the flat structure.

As shown in FIG. 1, a silicon substrate 1 has its top surface portion, in which a p-type well layer 2 and an n-type well layer 3 are formed. And, active regions of the n- and p-channel MISFETs are partitioned by a pattern of element isolation region 4 as formed by known shallow trench isolation (STI) techniques. In the active region of the n-channel MISFET, an n-channel interface layer 5 is formed at its channel surface, on which a patterned n-channel high dielectric material gate insulation film 6 and an n-channel gate electrode 7 are stacked with a pair of spaced-apart n-type source/drain diffusion layers 8 being formed in the active region to laterally oppose each other while letting the layer 5 and film 6 plus gate electrode 7 be interposed between the diffusions 8. Similarly in the p-channel MISFET active region, a p-channel interface layer 9 is formed at its channel surface, on which a patterned p-channel high dielectric gate insulator film 10 and a p-channel gate electrode 11 are multilayered with a pair of p-type source/drain diffusion layers 12 being formed to oppose each other while letting the layer 9 and film 10 plus gate 11 reside therebetween.

The prior art as stated in the introductory part of the description is such that in this flat-structure MISFET device, the high dielectric gate insulator films and gate electrodes for use in the n- and p-channel MISFETs are formed in such a way that these MISFETs are the same as each other in material and in structure. In contrast, in this invention, mutually different high dielectric gate insulator films and gate electrodes are formed in the n- and p-channel MISFETs. Respective cases will be discussed below.

(High Dielectric Gate Insulator Film)

In this invention, a high dielectric gate insulator film containing therein a less amount of nitrogen atoms (i.e., doped with no nitrogen atoms) is used for the gate insulation film of n-channel MISFET. As for the p-channel MISFET's gate insulation film, a high dielectric gate insulator film that is greater in nitrogen content than the former (doped with nitrogen) is used. Note here that the high dielectric gate insulator film is preferably made of high dielectric constant (high-k) film material which contains, as its main component, metal oxides such as HfO₂ or ZrO₂ as stated previously, metal silicates such as HfSiOₓ or ZrSiOₓ, metal aluminates such as HfAlOₓ or ZrAlOₓ, or lanthanoid oxides such as La₂O₃, Y₂O₃ and equivalents thereto. Alternatively, the high dielectric gate insulator film may be an insulative film with a multilayer structure of more than two dielectric films as selected from the high-k films made of the above-noted high-k materials. Preferably, the high dielectric gate insulator film made of the high-k materials is formed by known atomic layer deposition (ALD) methods or metal organic chemical vapor deposition (MOCVD) methods.

Some representative examples of the high dielectric gate insulator film are indicated in Table 1. Regarding a specimen A in Table 1, the interface layer (5, 9) at the channel surface shown in FIG. 1 is an SiO₂ film which is formed by rapid thermal oxidation (RTO) to a thickness of about 0.7 nanometers (nm), whereas the high-k film is formed of an HfSiOₓ film having a thickness of 2.5 nm. And, as post-processing of the high-k film formation, thermal processing called the post-deposition anneal (PDA) is done in (diluted) oxygen atmospheres. Regarding a sample B, the interface layer is an SiO₂ film that is formed by plasma oxidation (plasma Ox.) to a thickness of 0.5 nm at a substrate temperature of about 400° C., while the high-k film is formed of an HfO₂ film with a thickness of 2.5 nm. After having deposited the high-k film, plasma Ox. is executed. As for a sample C, no special processing is done for forming the interface layer on the channel surface. Here, the high-k film is formed of an HfO₂ film that is 3.0-nm thick. The plasma Ox. is done after deposition of the high-k film. In these samples, the sample C is the least in equivalent oxide thickness (EOT) of high dielectric gate insulator film; and, EOT increases in the order of the sample B and sample A. Optionally in the formation of the high dielectric gate insulator film, an interface layer comprised of an SiO₂ film may be formed by performing the above-noted thermal processing in oxygen atmospheres during the post-processing after having formed the high-k film.

TABLE 1

| | Interface | | After Film | |
|---|---|---|---|---|
| Sample | Layer | High-k Film | Formation | EOT (nm) |
| A | SiO₂ Film | HfSiOₓ Film | PDA | 1.6 |
| | 0.7 nm RTO | 2.5 nm | | |
| B | SiO₂ Film | HfO₂ Film | Plasma OX. | 1.3 |
| | 0.5 nm | 2.5 nm | | |
| | Plasma OX. | | | |
| C | — | HfO₂ Film | Plasma OX. | 1.1 |
| | | 3.0 nm | | |

The formation of the nitrogen-added high dielectric gate insulator film may be done by depositing by ALD techniques a high-k film made of the above-noted high dielectric constant film material and thereafter nitriding the high-k film or the interface layer by a plasma nitridation method which follows. In this plasma nitridation method, active species of nitrogen are generated by plasma excitation at electron cyclotron resonance (ECR) of a raw gas such as N₂ gas, N₂O, NO or else or alternatively by excitation in any one of an inductively coupled plasma (ICP), radio frequency (RF) plasma (of the magnetron type), and helicon-wave plasma. Then, let the active species fall onto a surface of the high-k film. While the active species contain nitrogen atom ions, molecular ions or neutral radicals or else, it is preferable here that only the neutral radicals be extracted and irradiated to the active species. An example is that those neutral radicals with comparatively long lifetime are extracted by down-flow techniques from the nitrogen active species thus formed in a plasma excitation chamber and are then irradiated. In the case of such plasma nitridation method using the neutral radicals of nitrogen, these nitrogen neutral radicals are controlled and limited to only one kind of radicals. Thus it becomes possible to precisely control the nitrogen concentration in the high dielectric gate insulator film along with the depth of resultant nitrided layer. In addition, this method is what is called the remote plasma scheme that offers an ability to prevent either the ion irradiation or plasma emission irradiation. Thus, irradiation damages in the high dielectric gate insulator film decrease drastically, thereby making it possible to ensure acquisition of high-quality gate insulator films. Another advantage of the plasma nitridation method described above is that the introduction amount or doping depth of nitrogen into the high dielectric gate insulator film is readily controllable by adjustment of either plasma processing conditions, such as electrical power of plasma excitation, or a length of processing time.

Note here that in case the active species are created by plasma excitation of hydrogen-containing raw gases such as N₂H₄ or NH₃ gases, the high-k film experiences hydrogen reduction. In view of this, it is preferable to eliminate the use of such gases.

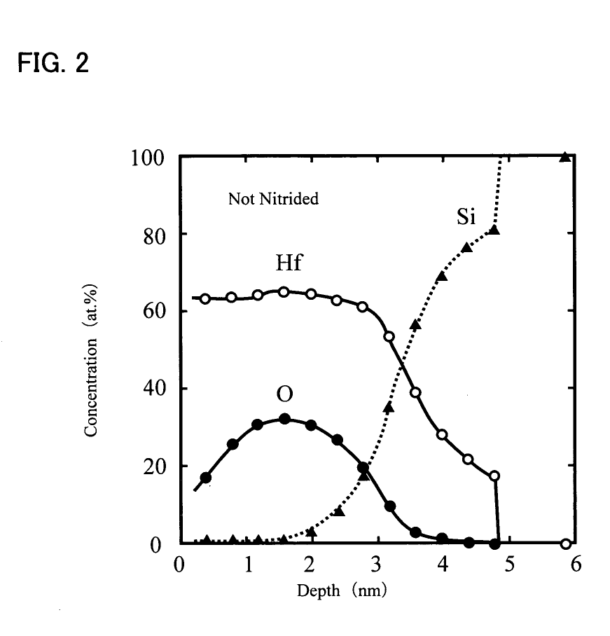

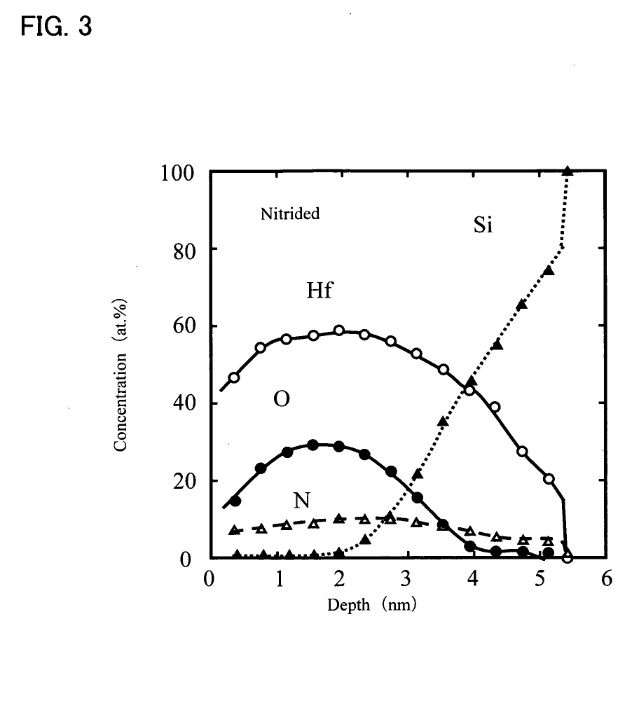

Next, the composition of the high dielectric gate insulator film will be explained with reference to FIGS. 2 and 3. FIG. 2 graphically shows an exemplary composition of the sample C with the thinnest EOT in Table 1; FIG. 3 is a composition example of a high dielectric gate insulator film resulted from the plasma nitridation of the sample C. The composition of high dielectric gate insulator film shown herein was obtained by high-resolution Rutherford back scattering (RBS) analysis.

As can be seen from FIG. 2, the interface layer of the sample C's high dielectric gate insulator film is of the type having an HfSiOₓ structure. Such film is nitrided while letting the concentration of nitrogen in the film stay at about 5 atomic percent (at. %) and also setting the interface layer's concentration to about 2 to 3 at. % as shown in FIG. 3. As far as this plasma nitridation is concerned, the concentration is preferably set to 1 at % or greater.

In this way, the high dielectric gate insulator film 6 is formed in the n-channel MISFET as explained in FIG. 1, which film is free from nitrogen doping and has its composition with no nitrogen contained therein as shown in FIG. 2. As for the p-channel MISFET, it is preferable to form the p-channel high dielectric gate insulator film 10 having its composition with nitrogen contained therein as shown in FIG. 3. Note here that for the above-noted plasma nitridation, a selective plasma nitridation technique with a mask adhered to n-channel MISFET formation areas is preferably employable.

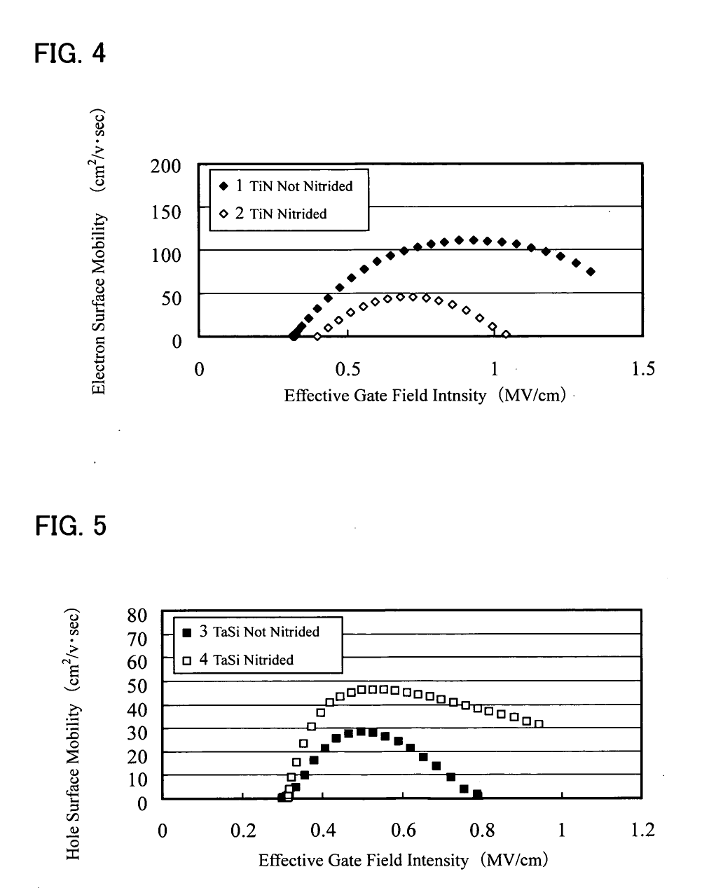

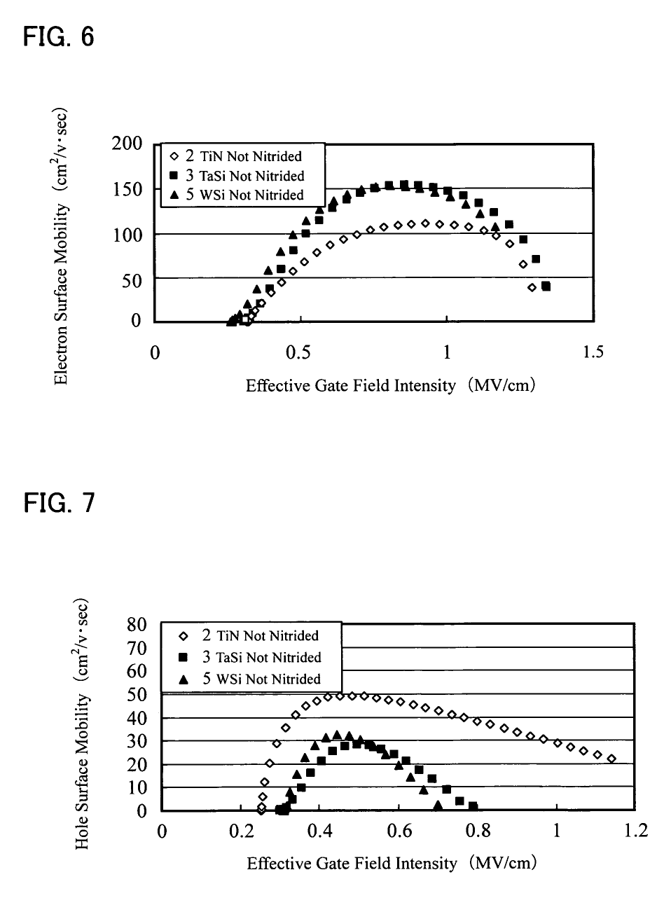

Using the high dielectric gate insulator films stated above makes it possible to increase both the electron mobility of n-channel MISFET and the hole mobility of p-channel MISFET at a time. Regarding this, an explanation will be given with reference to FIGS. 4 and 5. FIG. 4 is a graph showing the electron mobility in n-channel MISFET, whereas FIG. 5 is a graph showing the hole mobility of p-channel MISFET. In these graphs, the effective gate field intensity is taken along the lateral axis of coordinate; in the vertical axis, the surface mobility of respective carriers is indicated. In FIG. 4, the gate electrode is formed of a TiN film: open symbols are used to indicate a case where the high dielectric gate insulator film is applied the above-noted plasma nitridation processing; closed symbols indicate a case where the film is free from such nitridation processing. As apparent from viewing FIG. 4, the electron mobility decreases due to the nitridation of high dielectric gate insulator film to an extent equal to about one-half (½) of that in the case of no nitridation processing, at a point at which the effective gate field intensity is 0.7 megavolts per centimeter (MV/cm).

On the contrary, as shown in FIG. 5, the hole mobility of the p-channel MISFET increases due to the high dielectric gate insulator film's nitridation processing. In FIG. 5, the gate electrode is made of tantalum silicide (TaSi), wherein open symbols are in a case where the high dielectric gate insulator film is applied the above-noted plasma nitridation processing whereas closed symbols are in a case where the film is applied no nitridation treatment. An increase in hole mobility due to the nitridation is as large as about five thirds (5/3) times greater than that in the case of no nitridation, at a point whereat the effective gate field intensity is 0.5 MV/cm.

As the high dielectric gate insulator film is improved in thermal stability owing to the nitridation processing thereof, any appreciable changes in film composition no longer take place during thermal processes in the manufacture of semiconductor devices—in particular, even during thermal processing for activation of impurities (at a temperature of 850° C., for example). Especially, a change in composition due to interface reaction between the gate electrode and high dielectric gate insulator film is almost completely precluded. Furthermore, the above-noted plasma nitridation method is very simple and convenient methodology. Owing to these merits, it becomes easier to control the thickness of each gate insulation film. Thus it is possible to form the intended gate insulation film having a desired EOT value with good reproducibility.

The high dielectric gate insulator film nitridation processing should not exclusively be limited to plasma nitridation methods. Similar results are also obtainable by thermal process treatments including a film fabrication technique using nitrogen-containing raw gases, such as NH₃ or N₂H₄ gases, as will be described later.

(Gate Electrode)

In this invention, the gate electrode of the n-channel MISFET is arranged to employ a conductive film with no nitrogen atoms contained therein. In contrast, the gate electrode of p-channel MISFET is preferably designed to use a nitrogen-added conductive film. In the case of the n-channel MISFET, the n-channel gate electrode 7 for adhesion to the surface of n-channel high dielectric gate insulator film 6 shown in FIG. 1 is preferably made of conductor film materials including, but not limited to, metals such as Ti, Zr, Hf, V, Nb, Ta, Mo, W and others, metal silicides such as TiSiₓ, ZrSiₓ, HfSiₓ, VSiₓ, NbSiₓ, TaSiₓ, MoSiₓ, WSiₓ, NiSiₓ, CoSiₓ or the like, and metal carbides such as TiCₓ, ZrCₓ, HfCₓ, VCₓ, NbCₓ, TaCₓ, MoCₓ, WCₓ and equivalents thereto. In addition, the n-channel gate electrode 7 may be a single-layer structure of one of the above-noted metals, metal silicides and metal carbides or alternatively may be a multilayer structure of more than two of them. Still alternatively, the gate may be designed to have a multilayer structure of a film made of one of these conductor film materials (having a thickness of 1 nm or more) and a low-resistivity film deposited thereon, which is made of tungsten (W), aluminum (Al) or impurity-doped silicon. This conductor film is formed by sputter methods such as physical vapor deposition (PVD), chemical vapor-phase growth methods such as chemical vapor deposition (CVD), atomic layer deposition (ALD) methods or else.

The p-channel gate electrode 11 for adhesion onto the surface of p-channel high dielectric gate insulator film 10 is preferably formed of a nitrogen-containing conductor film that is made of metal nitrides such as TiNₓ, ZrNₓ, HfNₓ, VNₓ, NbNₓ, TaNₓ, MoNₓ, WNₓ and others or conductive materials such as TiSiₓN_{y}, ZrSiₓN_{y}, HfSiₓN_{y}, VSiₓN_{y}, NbSiₓN_{y}, TaSiₓN_{y}, MoSiₓN_{y}, WSiₓN_{y} and equivalents thereof. Additionally, the p-channel gate electrode 11 may be a single-layer structure of any one of the above-noted nitrogen-containing conductor film materials or alternatively may be a multilayer structure of more than two of them. Still alternatively, the gate may have a multilayer structure of a film made of one of these conductive materials (with its thickness of 1 nm or greater) and a low-resistivity film deposited thereon, which is made of W, Al or impurity-doped silicon.

Note here that the nitrogen-containing conductor film is formed by PVD, CVD or ALD methods. For instance, in the case of forming a TiN film, this film is formed by CVD methods at a temperature of about 600° C. while using as raw gases a titanium tetrachloride (TiCl₄) gas and an ammonia (NH₃) gas. With this film formation technique, the surface of the high dielectric gate insulator film undergoes thermal treatment using the nitrogen-containing raw gas such as NH₃ or N₂H₄ gas as stated above. For this reason, the high dielectric gate insulator film also is forced to experience nitridation simultaneously.

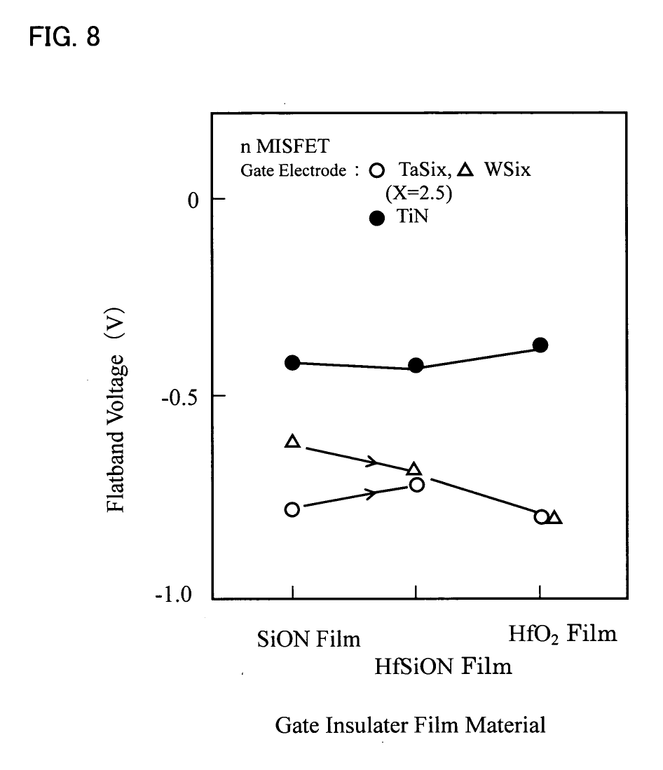

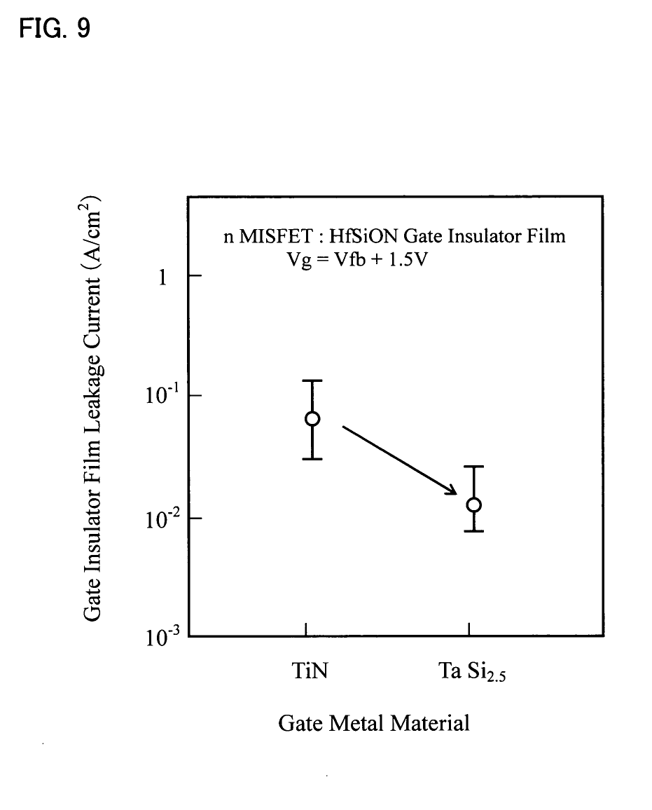

Using the above-stated gate electrodes makes it possible to increase both the electron mobility of n-channel MISFET and the hole mobility of p-channel MISFET at a time. This will be explained with reference to FIGS. 6 and 7. FIG. 6 is a graph showing measured values of the electron mobility in the n-channel MISFET, whereas FIG. 7 is a graph showing the hole mobility of p-channel MISFET. In these graphs, the effective gate field intensity is plotted along the lateral coordinate axis; in the vertical axis, the surface mobility of carrier change is indicated. Here, the high dielectric gate insulator film is formed as in the above-noted sample C with EOT being minimized, wherein the plasma nitridation is not applied thereto. In FIG. 6, open symbols are in a case where the gate electrode is a TiN film whereas closed symbols are in a case where it contains no nitrogen as in a TaSi film or tungsten silicide (WSi) film. As apparent from FIG. 6, the electron mobility increases in case the gate electrode does not contain nitrogen, and is 3/2 times greater than that of the TiN film when the effective gate field intensity is at 0.7 MV/cm.

In contrast, as shown in FIG. 7, the hole mobility of p-channel MISFET increases adversely in case the gate electrode contains nitrogen. In FIG. 7, open symbols are in a case where the gate electrode is a TiN film, and closed symbols are in a case where the gate contains no nitrogen as in the TaSi film or WSi film. As can be seen from FIG. 7, the hole mobility increases by addition of nitrogen to the gate electrode so that it is as large as about 5/3 times greater than that of a nitrogen-free gate electrode when the effective gate field intensity is 0.5 MV/cm.

As previously stated, it was demonstrated that the nitrogen to be contained in the MISFET gate region is effective at letting the p-channel MISFET increase in hole mobility while at the same time permitting the n-channel MISFET to decrease in electron mobility. Accordingly, in those MISFETs having high dielectric gate insulator films, n-channel MISFETs are specifically designed so that each contains no nitrogen in its high dielectric gate insulator film while simultaneously preventing nitrogen containment of a gate electrode in contact with the surface of such high dielectric gate insulator film. For p-channel MISFETs, each is designed to allow nitrogen to be contained in its high dielectric gate insulator film or in a gate electrode in contact with this film. With this approach, it is possible to readily obtain a complementary MISFET having high dielectric gate insulator films with both the electron mobility and the hole mobility increased together. This permits the n- and p-channel MISFETs to increase in current drivability, resulting in improvements in operation speeds thereof. Owing to this advantage, it becomes easier to achieve higher speed performance and lower power consumption of a semiconductor device made up of these complementary MISFETs, which in turn enables practical implementation of an ultra-high performance semiconductor device.

Alternatively, in a complementary MISFET having a high dielectric gate insulator film(s), specific chip designs are made so that the nitrogen contained in either the high dielectric gate insulator film of a p-channel MISFET or its gate electrode in contact with a surface of the high dielectric gate insulator film is greater in amount than the nitrogen which is contained in a high dielectric gate insulator film of n-channel MISFET and a gate electrode contacted with a surface of such n-channel gate insulator. By doing so, in addition to the advantages stated above, the electron mobility and hole mobility come closer in value to each other, resulting in facilitation of the design procedure of a semiconductor device made up of the above-noted complementary MISFET.

Another feature of the invention is that the n-channel gate electrode 7 of n-channel MISFET is made of a specific conductor film material of the above-noted metal slicides, which is a metal silicide containing therein an excessive amount of silicon (Si) that is out of the stoichiometric composition (as will also be referred to hereinafter as “silicon-rich” metal silicide). Examples of the Si-rich metal silicide are those of the above-noted conductor materials, such as TiSiₓ, ZrSiₓ, HfSiₓ, VSiₓ, NbSiₓ, TaSiₓ, MoSiₓ, WSiₓ, NiSiₓ and CoSiₓ, which have the value of suffix “x” that is in excess of two (2). Other examples are metal silicides of NiSiₓ with the x value being greater than one (1). Alternatively, a conductor film material having a multilayer structure of them is employable. Although the silicon-rich metal silicides are capable of being formed by PVD, CVD or ALD methods, the resulting layer or membrane can exhibit not only a thermally stable phase but also a metastable phase or unstable phase, so a need is felt to perform thermal processing after film fabrication at maximally reduced temperatures (for example, at 600° C. or below).

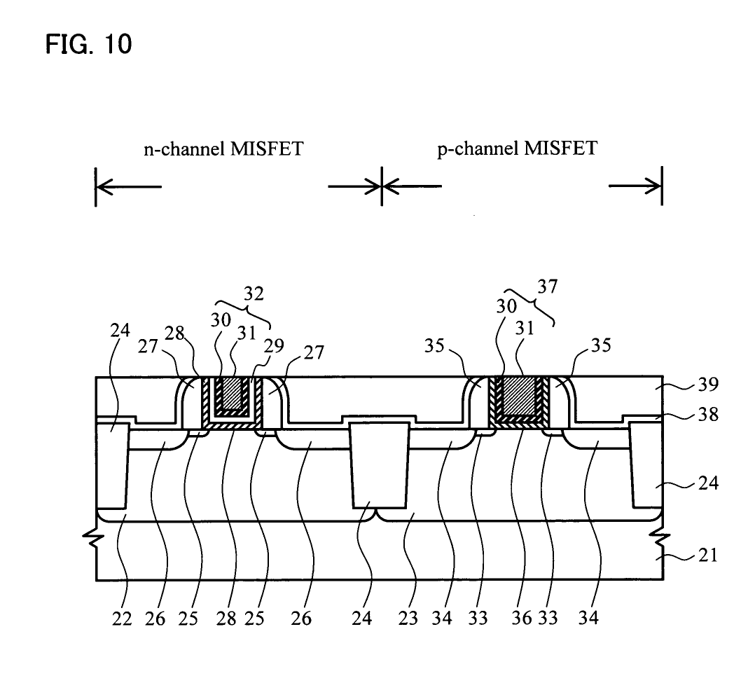

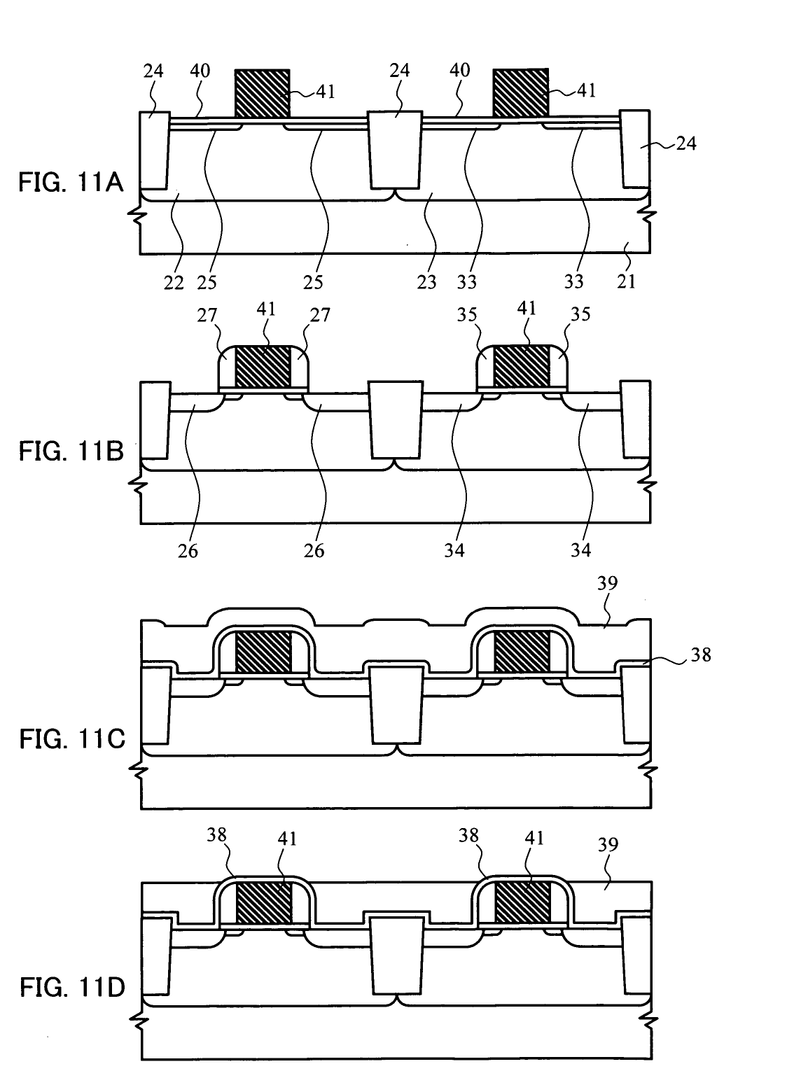

By using such the silicon-rich metal silicides for the metallic material of the gate electrode of n-channel MISFET, it is possible to permit the Fermi level of a gate metal to come nearer to the edge of a conduction band of Si while at the same time improving the insulation properties of high dielectric gate insulator film. Regarding this, an explanation will be given with reference to FIGS. 8 and 9. FIG. 8 is a graph showing the flat-band voltage of n-channel MISFET with the kind of gate electrode metal material as a parameter, wherein its lateral axis indicates kinds of high dielectric gate insulator films while its vertical axis indicates the flatband voltage. FIG. 9 is a graph showing a change in leakage current flowing in a high dielectric gate insulator film when this film is kept constant in potential, wherein the lateral axis indicates the kind of gate electric metal material whereas the vertical axis indicates the leakage current of gate insulator film.

The flatband voltage (Vfb) is obtained from the so-called capacitor-to-gate voltage (C-V) characteristics of the n-channel MISFET. The flatband voltage may be represented by Vfb=Φms-Qox/Cox, where, as well known, Φ is the Fermi level difference between the metal of gate electrode and the semiconductor surface, and Qox/Cox is equivalent to a gate voltage which compensates for residual charge carriers in the gate insulator film in case the semiconductor surface's band structure is made flat (Qox is the amount of charge in gate insulator film, and Cox is the capacitance of gate insulator film). A characteristic matter in FIG. 8 is that in case the gate electrode metal material is comprised of TaSiₓ and WSiₓ (x=2.5), and when the high dielectric gate insulator film is made of a high dielectric constant (high-k) film material of HfSiON (oxynitride film) and HfO₂, the flatband voltage gets higher on the negative side (this is equivalent to an increase in Fermi level of gate electrode metal), and moreover, TaSiₓ and WSiₓ become almost the same as each other in flatband voltage value as indicated by arrows in FIG. 8. It is considered that this is due to the creation of a phenomenon which follows: at the junction of the TaSiₓ or WSiₓ material relative with the high-k film material in a gate region that becomes a multilayer structure, the Fermi level of gate electrode is fixed or “pinned” within a certain range irrespective of the gate electrode material. This phenomenon is known as Fermi level pinning. Although this phenomenon per se is often observable in silicon gate electrodes as well known among those skilled in the semiconductor device art, the inventors found out that the use of silicon-rich metal silicides makes it possible to obtain a work function that is suitable for certain n-channel MISFET gate electrode.

In the n-channel MISFET, it becomes possible to lower the flatband voltage by utilizing the above-noted phenomenon while using the silicon-rich metal silicides for the metal of gate electrode and using the high-k material for the gate insulator film in the way stated supra. As well known, the n-channel MISFET's threshold voltage (Vt) is given as Vt=Vfb+2 ψf+Qb/Co, where ψf is the difference between Fermi level and mid gap level at semiconductor surface, Qb is the space charge amount (per unit area) of a surface depletion layer when the semiconductor surface is in a deep inversion state (in a surface band bending state of “2 ψf” in the equation above), and Co is a capacitance value (per unit area) of gate insulator film in this state. As it becomes easier to lower the flatband voltage, it is possible to reduce the n-channel MISFET threshold voltage and thus increase the current drivability.

As shown in FIG. 8, in case the gate electrode's metal material is a TiN film, the above-noted Fermi level pinning no longer takes place. In this case, the work function is greater than that of metal silicides, resulting in accomplishment of the metal material preferably adaptable for p-channel MISFET gate electrodes. Additionally, the Fermi level pinning hardly occurs in case the gate insulator film is formed of a silicon oxynitride (SiON) film.

As previously stated, when using the silicon-rich metal silicides as the gate electrode metal material of n-channel MISFET, the problem as to an increase in leakage current in high dielectric gate insulator films as discussed in the prior art is also alleviated without difficulties. See FIG. 9, which shows in a comparative way the cases of TiN and TaSiₓ (x=2.5) for causing the metal material to become suitably adaptable for use as the gate electrode of p-channel MISFET. As can be seen from FIG. 9, the leakage current in high dielectric gate insulator film is reduced by using TaSiₓ (x=2.5) as the metal material in n-channel MISFET so that it is approximately 1/10 of that in case TiN is chosen as the metal material. Such improvement in insulation properties of high dielectric gate insulator film is frequency seen in almost all of the above-noted silicon-rich metal silicides, although the decrement of gate insulator film leakage current is somewhat different in a way depending upon metal silicide materials.

Although in the above-described embodiment 1 the high dielectric gate insulator film is concretely explained with respect to the case of the sample C in Table 1, the same or similar effects are also obtainable when the invention is applied to the sample A or B. In case sample A, B is used to form a high dielectric gate insulator film, the electron mobility and hole mobility further increase as a whole to an extent larger than the case of sample C, resulting in the complementary MISFET exhibiting higher performance. This can be said because an SiO₂ interface layer is formed in an interface region between the silicon substrate and the high dielectric gate insulator film. When employing silicon-rich metal silicides for the n-channel MISFET gate electrode material while adding nitrogen to the high dielectric gate insulator film or the gate electrode of p-channel MISFET, a high drive current is achievable in the turn-on state of each MISFET as can be seen from the foregoing description. This results in a likewise decrease in leakage current in channel region in the turn-off state thereof. Thus it is possible to realize a complementary MISFET with further enhanced performance.

In the MISFET structure stated above, the source/drain regions may be structurally arranged so that an extension layer is formed or alternatively may be designed to have a halo structure. Optionally, the silicon substrate 1 may be replaced by a silicon-on-insulator (SOI) substrate.

### Embodiment 2

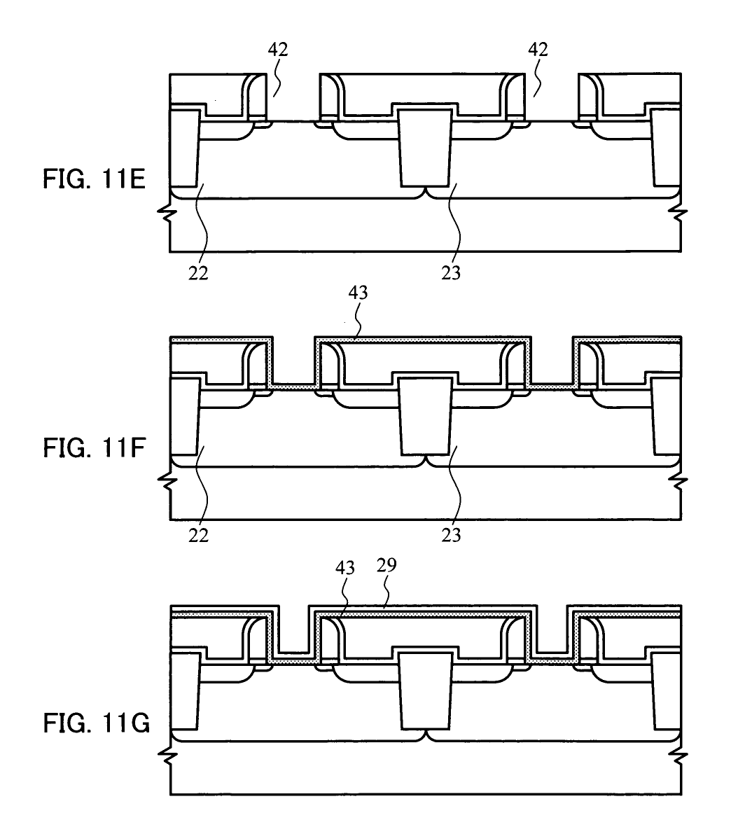

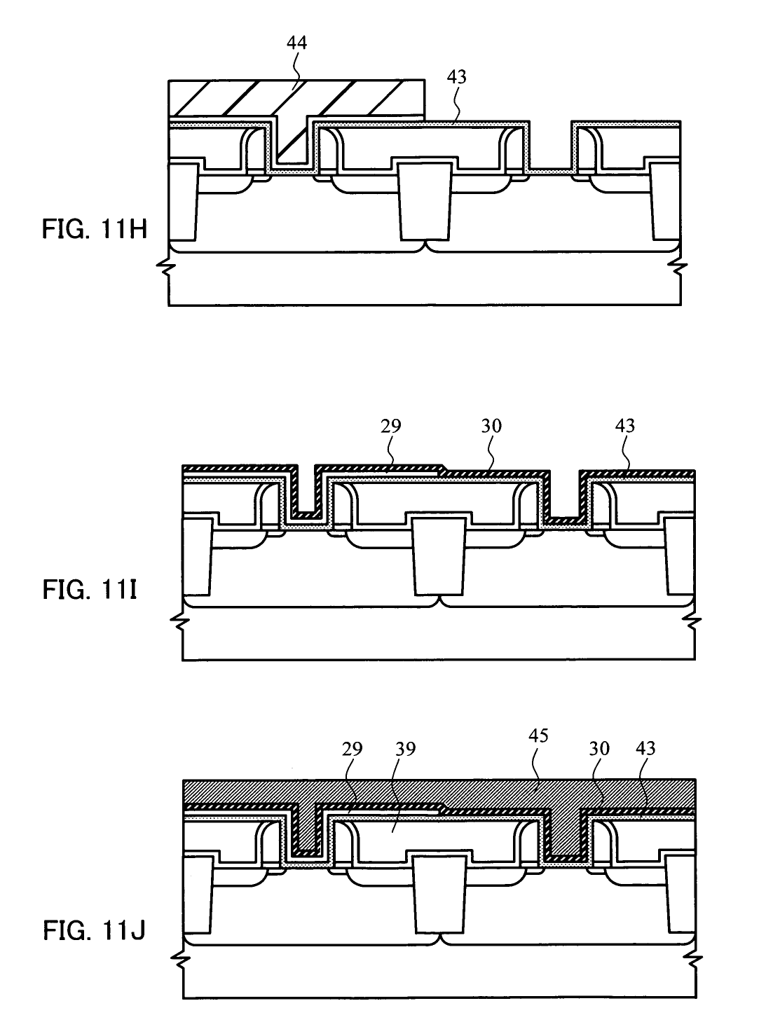

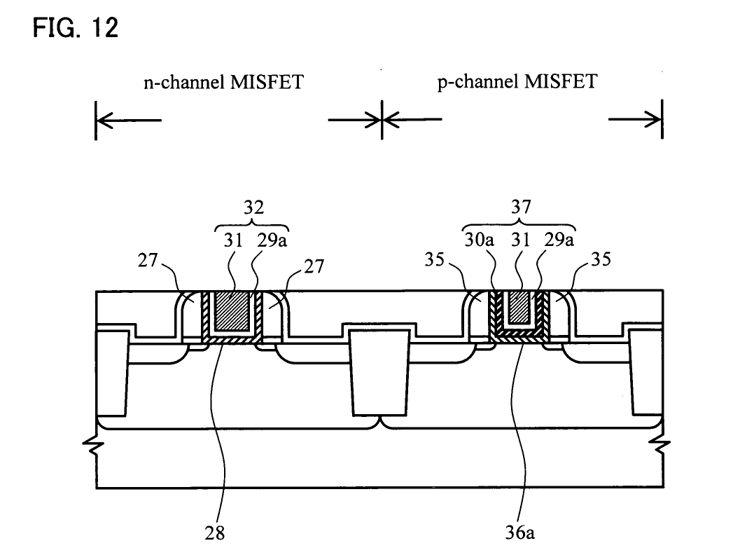

An explanation will next be given of a case where this invention is applied to a MISFET device of the type having a damascene gate electrode structure with reference to FIGS. 10, 11A-11J and 12 below. FIG. 10 illustrates, in cross-section, a complementary MISFET device incorporating the principles of the invention, and FIGS. 11A-11J depict in cross-section some major steps in the manufacture of the device. FIG. 12 is a sectional view of a modified example of the MISFET device, also embodying the invention.

As shown in FIG. 10, a silicon substrate 21 has its top surface in which a p-well layer 22 and an n-well layer 23 are formed. Active region of an n-channel MISFET and n-channel MISFET are partitioned by an STI element isolation layer 23. In the n-channel MISFET active region, a pair of laterally opposing n-type extension layers 25 and a pair of n-type source/drain diffusion layers 26 are formed so that each extension is coupled to its associated diffusion. At upper portions thereof, a pair of n-channel gate sidewalls 27 comprised for example of a silicon nitride film are provided so that these oppose each other. In a groove defined by the pair of opposite n-channel gate sidewalls 27, an n-channel high dielectric gate insulator film 28 having a high-k film with no nitrogen doped thereinto, a nitrogen-nondoped conductor film 29, a nitrogen-doped conductor film 30 and a metallic electrode 31 are formed and stacked sequentially in this order. The nitrogen-free conductor film 29 and nitrogen-doped conductor film 30 plus metal electrode 31 make up an n-channel gate electrode 32 of the n-channel MISFET with the metal gate electrode structure.

Similarly, in the p-channel MISFET active region, a pair of opposing p-type extension layers 33 and a pair of p-type source/drain diffusion layers 34 are formed so that respective corresponding ones are coupled together. At upper portions thereof, a pair of p-channel gate sidewalls 35 made for example of a silicon nitride film are provided so that these oppose each other. In a groove defined by the pair of opposite p-channel gate sidewalls 35, a p-channel high dielectric gate insulator film 36 having a nitrogen-doped high-k film, a nitrogen-doped conductor film 30 and a metal electrode 31 are multilayered in sequence. Here, the nitrogen-added conductor film 30 and metal electrode 31 constitute a p-channel gate electrode 37 of the p-channel MISFET with the metal gate electrode structure.

A contact etch stopper layer 38 made up of a silicon nitride film for example and an interlayer dielectric (ILD) film 39 made of silicon oxide are formed and multilayered to cover an almost entire structure in a similar way to the prior art.

In the MISFET structure stated above, the nitrogen-free n-channel high dielectric gate insulator film 28 is formed to have the arrangement such as shown in Table 1. The nitrogen-added p-channel high dielectric gate insulator film 36 is formed simultaneously during the plasma nitridation such as discussed in the embodiment 1 or during formation of a nitrogen-added conductor film 30 to be later described.

The nitrogen-free conductor film 29 is arranged to have a thickness of 1 nm or more-preferably, about 10 nm. This nitrogen-free conductor film 29 is preferably made of metals such as Ti, Zr, Hf, V, Nb, Ta, Mo, W and others, metal silicides such as TiSiₓ, ZrSiₓ, HfSiₓ, VSiₓ, NbSiₓ, TaSiₓ, MoSiₓ, WSiₓ, NiSiₓ, CoSiₓ or the like, or metal carbides such as TiCₓ, ZrCₓ, HfCₓ, VCₓ, NbCₓ, TaCₓ, MoCₓ, WCₓ and equivalents thereto, as stated previously. Alternatively, film 29 may be designed to have a structure with a multilayer of more than two kinds of materials as selected from the above-noted metals, metal silicides and metal carbides. Additionally, when the conductor film material is contacted with the silicon substrate's top surface with the high dielectric gate insulator film 28 sandwiched therebetween, if its work function is nearer to the silicon's conduction band side rather than the mid gap (center of a forbidden band), then those conductor film materials other than the above-noted ones are also suitably usable. Examples of such material are metal silicides out of the above-noted conductor film materials such as TiSiₓ, ZrSiₓ, HfSiₓ, VSiₓ, NbSiₓ, TaSiₓ, MoSiₓ, WSiₓ, NiSiₓ and CoSiₓ, with the x value being set to 2 or greater. Other examples are metal silicides with the x value being in excess of 1 in the NiSiₓ-based conductor film materials.

The nitrogen-added conductor film 30 is preferably made of TiNₓ, ZrNₓ, HfNₓ, VNₓ, NbNₓ, TaNₓ, MoNₓ, WNₓ, or alternatively made of TiSiₓN_{y}, ZrSiₓN_{y}, HfSiₓN_{y}, VSiₓN_{y}, NbSiₓN_{y}, TaSiₓN_{y}, MoSiₓN_{y}, WSiₓN_{y} or else. Alternatively this film may be a structure with a multilayer of more than two of the above-noted nitrides. The metal electrode 31 is preferably made of low-resistance metals such as W, Al, copper (Cu) or alloys of Al or Cu.

A method for fabricating the above-noted semiconductor device in accordance with the invention will next be explained with reference to FIGS. 11A to 11J. In FIGS. 11A-11J, parts or components similar to those of FIG. 10 are indicated by the same reference numerals.

An STI element isolation region 24 is provided in a selected surface portion of silicon substrate 21. Thereafter, a p-well layer 22 and n-well layer 23 are formed by ion implantation and thermal processing, respectively. Then, a surface protection film 40 made of silicon oxide is formed by thermal oxidation on each well surface to a thickness of about 5 nm. Next, known lithography and dry etch techniques are used to form thereon patterned dummy gate electrodes 41 made of polysilicon or amorphous silicon, to a thickness of about 100 nm. Here, the film thickness of dummy gate electrodes 41 is determined by taking account of the height of gate electrodes of the damascene structure to be formed later. Furthermore, ion implantation is performed with respect to the dummy gate electrodes 41 in a self-align manner, followed by execution of thermal processing, resulting in n-type extension layers 25 and p-type extension layers 33 being formed in exposed surface portions of p-well layer 22 and n-well layer 23, respectively (see FIG. 11A). Optionally, chosen ions of the opposite conductivity type to that of the extension layers 25 may be doped by implantation into the dummy date electrodes 41 in a self-align fashion, thereby to form a so-called halo layer(s).

Next, after having chemically vapor-deposited a silicon nitride film on an entire surface to a thickness of about 8 nm, etch-back is performed by reactive ion etching (RIE) to thereby form n- and p-channel gate sidewalls 27 and 35. Then, ion implantation is done in self-align with respect to the dummy gate electrodes 41 and gate sidewalls 27 and 35, followed by execution of thermal processing, thereby forming n-type source/drain diffusion layers 26 in the surface of p-well layer 22 while forming p-type source/drain diffusions 34 in the surface of n-well 23 (see FIG. 11B). Here, selected portions of the surface protection film 40 that overlie the surfaces of n- and p-source/drain diffusions 26 and 34 are removed away by etching.

Next, as shown in FIG. 11C, a contact etch stopper layer 38 comprised of a silicon nitride film and a silicon-oxide interlayer dielectric (ILD) film 39 are chemically vapor-deposited so that these are multilayered. Then, while using as a polishing stopper certain portions of the contact etch stopper layer 38 which overlie the dummy gate electrodes 41, the ILD film 39 is surface-polished by chemical mechanical polish (CMP) techniques, thereby causing the etch stopper layer 38 to expose at its portions overlying the dummy gate electrodes 41 while letting the surface of ILD film 38 be made flat or “planarized” as shown in FIG. 11D.

Next, the selectively exposed contact etch stopper layer 38 and the dummy gate electrodes 41 are etched away by RIE or else to thereby form grooves 42. Here, portions of the surface protector film 40 residing at the bottoms of these grooves 42 are removed by wet etching, resulting in the surfaces of p- and n-wells 22-23 being exposed as shown in FIG. 11E.

Next, as shown in FIG. 11F, a high-k film 43 with a thickness of about 2 to 3 nm is formed by ALD methods or else so that film 43 covers an entire surface. Although the high-k film 43 is preferably made of HfO₂, HfSiOₓ or HfAlOₓ, film 43 may alternatively be a ZrO₂ film or a high-k film made of IIIa-group oxides, such as Y₂O₃, La₂O₃ or else, when a need arises.

In pre-processing of the formation of the high-k film 43, that is, at the step of FIG. 11E, an interface layer such as shown in Table 1 may be formed by an SiO₂ film after having selectively exposed the surfaces of p- and n-wells 22-23. Also note that thermal processing may be executed in oxidation atmospheres as the post-processing of the formation of high-k film 43 as shown in Table 1. Owing to this film formation post-processing, the high-k film 43 is improved in insulation properties as stated supra. Another advantage of this post-processing lies in the capability of electrically stabilizing the interface layer between the high-k film 43 and the surfaces of p- and n-wells 22-23.

Next, as shown in FIG. 11G, a nitrogen-free conductor film 29 of 1 to 10 nm in thickness is formed by ALD methods as a first conductive film in such a way as to cover or coat the high-k film 43.

Next, as shown in FIG. 11H, known lithography techniques are used to form a patterned resist mask 44. With this resist mask 44 used as an etching mask, a portion of the nitrogen-free conductor film 29 that lies in the substrate surface area in which a p-channel MISFET is to be formed is selectively etched and removed away. Although this etching may be RIE, wet etching is preferable because of its ability to eliminate damages of its underlying high-k film 43. For example, the high-k film 43 is made of HfO₂ whereas the nitrogen-free conductor film 29 is made of TiSiₓ, ZrSiₓ, HfSiₓ, VSiₓ, NbSiₓ, or TaSiₓ. If this is the case, it is possible to wet etch the nitrogen-free conductor film 29 by using a hydrofluoric acid (HF)-based chemical solution as the etchant, without damaging the high-k film 43 (see FIG. 11H).

Next, as shown in FIG. 11I, after having removed the resist mask 44, a nitrogen-added conductor film 30 is formed by CVD as a second conductive film at a temperature of about 600° C. to a thickness of 1 to 10 nm in a way such that film 30 covers the high-k film 43 and nitrogen-free conductor film 29 in the substrate surface area in which the p-channel MISFET is to be formed. Raw gases as used herein are TiCl₄ and NH₃ gases, for example. During formation of the nitrogen-doped conductor film 30, the high-k film 43 in the p-channel MISFET area also is expected to undergo nitridation simultaneously, resulting in a nitrogen-doped p-channel high dielectric gate insulator film 36 of FIG. 1 being formed in this area. Owing to the nitridation, the p-channel high dielectric gate insulator film 36 is doped with nitrogen to a content of about 1 to 10 at %.

Note here that in order to add the nitrogen to the high-k film 43 in the p-channel MISFET area, a nitridation process using plasma nitridation methods may also be introduced prior to the formation of the conductor film 30.

Subsequently, as shown in FIG. 11J, a metallic film 45 is formed by CVD, ALD, PVD or plating methods to cover the entire surface so that its underlying grooves are buried. Metal film 45 is made of W, Al, Al alloys, Cu or Cu alloys, for example. Then, thermal processing is applied in a hydrogen-containing atmosphere at temperatures ranging from 150 to 300° C. when Cu or Cu alloy is used, or at temperatures of 400 to 450° C. in other cases. Thereafter, CMP methods are used to sequentially micro-grind or polish the metal film 45, nitrogen-added conductor film 30, nitrogen-free conductor film 29 and high-k film 43 with the interlayer dielectric (ILD) film 39 as a stopper therefor, thus removing unnecessary portions on the surface of ILD film 39 outside of the STI grooves 42. In this way, the intended metal electrodes 31 are formed in grooves defined by n-channel gate sidewalls 27 or p-channel gate sidewalls 35 as shown in FIG. 10, resulting in completion of the n- and p-channel MISFETs of FIG. 10. In a later process subsequent thereto, contact holes are formed in ILD film 39 to a depth reaching the source/drain diffusion layers by way of example, followed by formation of a pattered wiring layer for electrical interconnection with the source/drain diffusions through the contact holes, although not specifically illustrated herein.

A modification of the complementary MISFET of the embodiment 2 will be explained with reference to FIG. 12. The explanation below is mainly directed to its differences from the embodiment shown in FIG. 10, with explanations of the same ones eliminated herein. Similar parts or components to those of FIG. 10 are indicated by the same numerals.

As shown in FIG. 12, an n-channel MISFET is structured to have a nitrogen-nondoped n-channel high dielectric gate insulator film 28, a nitrogen-free conductor film 29a and a metal electrode 31, which are sequentially stacked within a groove defined and partitioned by a pair of opposing n-channel gate sidewalls 27. The nitrogen-free conductor film 29a and metal electrode 31 make up an n-channel gate electrode 32 of the n-channel MISFET, which is of the metal structure.

Similarly, a p-channel MISFET has a nitrogen-free p-channel high dielectric gate insulator film 36a, nitrogen-added conductor film 30a, nitrogen-free conductor film 29a and metal electrode 31, which are sequentially multilayered within a groove defined by a pair of opposite p-channel gate sidewalls 35. Here, the nitrogen-doped conductor film 30a, nitrogen-free conductor film 29a and metal electrode 31 constitute a metal gate structure p-channel gate electrode 37 of the p-channel MISFET. The metal electrode 31 is made of a low-resistance metal, such as W, Al or Cu, or alloys of Al or Cu.

In the formation of the complementary MISFET of the cross-sectional structure shown in FIG. 12, unlike the structure of FIG. 10, a process to be done after having formed the high-k film 43 is as follows. Firstly, deposit a nitrogen-added conductor film 30a as the second conductive film. Then, selectively remove a portion of the nitrogen-doped conductor film 30a which is deposited in the n-channel MISFET area. Thereafter, deposit a nitrogen-free conductor film 29a as the first conductive film. It is necessary here to deposit the nitrogen-doped conductor film 30a while preventing nitrogen from being doped into the n-channel high dielectric gate insulator film 28. To this end, the nitrogen-doped conductor film 30a may be a layer of one of the above-stated materials such as TiNₓ, ZrNₓ, HfNₓ, VNₓ, NbNₓ, TaNₓ, MoNₓ and WNₓ or a layer of TiSiₓN_{y}, ZrSiₓN_{y}, HfSiₓN_{y}, VSiₓN_{y}, NbSiₓN_{y}, TaSiₓN_{y}, MoSiₓN_{y} or WSiₓN_{y} or a multilayer structure of two or more layers of these nitrides, which layer or structure is formed by ALD or CVD methods at low temperatures ranging from 200 to 300° C. With such low-temperature film fabrication, the n-channel high dielectric gate insulator film 28 is no longer doped with nitrogen. The p-channel high dielectric gate insulator film 36a also is free from nitrogen doping risks.

An advantage of the embodiment 2 is as follows. As in the case of the embodiment 1, it is possible to increase both the electron mobility in the n-channel MISFET and the hole mobility of p-channel MISFET at a time. This enables the n- and p-channel MISFETs to increase in operation speeds, which in turn facilitates speed-up of a semiconductor device made up of these MISFETs. Another advantage is that in the case of this damascene-structure gate electrode, it is possible to lower the temperature of thermal process after having formed the high-k film making up the high dielectric gate insulator film. Thus it becomes possible to greatly reduce or minimize the heat damageability of the high-k film, thereby enabling formation of high-quality high dielectric gate insulator films excellent in insulating properties. A further advantage lies in an ability to readily form the intended metal gate that exhibits no thermal reactions on the surface of its associated high dielectric gate insulator film. This makes it possible to further enhance the speed performance of the semiconductor device due to a decrease in gate electrode resistance.

Alternatively, in the embodiment 2 also, an attempt is made to increase the amount of nitrogen being doped into the high dielectric gate insulator film of p-channel MISFET or the gate electrode in contact with the surface of such high dielectric gate insulator film to an extent greater than the amount of nitrogen contained in the high dielectric gate insulator film of n-channel MISFET and in the gate electrode contacted with the surface of the high dielectric gate insulator film. With such an arrangement, it is possible to cause the electron mobility and the hole mobility to come closer in value to each other. Thus it becomes easier to design a semiconductor device having such complementary MISFET.

Although this invention is described in terms of specific embodiments, the description is illustrative of the invention and is not to be construed as limiting the invention. Various modifications and applications may occur to those skilled in the art without departing from the true spirit and scope of the invention.

For example, the high-k film stated supra may alternatively be made of other kinds of metal oxides, such as alumina (Al₂O₃), tantalum oxide (Ta₂O₅), strontium titanate (STO) and barium strontium titanate (BST), or ferroelectric material such as lead zirconate titanate (PZT) or else.

While in the embodiments the metal silicate film for use as the high-k film is made of hafnium silicate or zirconium silicate, this film may alternatively be made of others, including lanthanoid-based silicates such as La₂O₃, Y₂O₃ or high-melting-point metal silicates, or any possible compounds of these materials.

Regarding the metal aluminate film for use as the high-k film, this may alternatively be made of other materials than hafnium alminates or zirconium alminates as set forth in the illustrative embodiments. Example of such materials are lanthanoid-based alminates such as La₂O₃ and Y₂O₃, high-melting-point metal alminates, and further any possible compounds thereof. Optionally a composite film of silicate and aluminate films is also employable.

The invention is also applicable, in a similar way, to semiconductor devices of the type having MISFETs formed on a compound semiconductor substrate made of GaAs or GaN or else, rather than the silicon substrate stated supra.

What is claimed is:

1. A semiconductor device having a p-channel metal insulator semiconductor field effect transistor (“MISFET”) and an n-channel MISFET each having a gate insulation film and a metal gate electrode above a semiconductive substrate, the gate insulation film being formed using a high dielectric constant film higher in dielectricity than a silicon oxide film, wherein
an amount of nitrogen contained in any one of said gate insulation film of said p-channel MISFET and a portion of said metal gate electrode thereof in contact with a surface of said gate insulation film is greater than an amount of nitrogen contained in any one of said gate insulation film of said n-channel MISFET and a portion of said metal gate electrode thereof as contacted with a surface of said gate insulation film.

2. The device according to claim 1, wherein said gate insulation film of said n-channel MISFET and said metal gate electrode at the portion in contact with the gate insulation film surface of said n-channel MISFET are formed so that the amount of nitrogen contained therein is substantially zero.

3. The device according to claim 1, further comprising:
an interface layer formed of a silicon oxide film as interposed between said semiconductive substrate and said high dielectric constant film.

4. The device according to claim 1, wherein said metal gate electrode at the portion contacted with the gate insulation film surface of said p-channel MISFET is made of at least one kind of conductive material as selected from the group consisting of TiNₓ, ZrNₓ, HfNₓ, VNₓ, NbNₓ, TaNₓ, MoNₓ, WNₓ, TiSiₓN_{y}, ZrSiₓN_{y}, HfSiₓN_{y}, VSiₓN_{y}, NbSiₓN_{y}, TaSiₓN_{y}, MoSiₓN_{y}, and WSiₓN_{y}.

5. The device according to claim 1, wherein said metal gate electrode at the portion contacted with the gate insulation film surface of said n-channel MISFET is made of at least one kind of conductive material selected from the group consisting of Ti, Zr, Hf, V, Nb, Ta, Mo, W, TiSiₓ, ZrSiₓ, HfSiₓ, VSiₓ, NbSiₓ, TaSiₓ, MoSiₓ, WSiₓ, NiSiₓ, CoSiₓ, TiCₓ, ZrCₓ, HfCₓ, VCₓ, NbCₓ, TaCₓ, MoCₓ and WCₓ.

6. The device according to claim 5, wherein said metal gate electrode at the portion contacted with said gate insulation film surface of said n-channel MISFET is made of a metal silicide with its silicon amount being greater than a stoichiometric composition ratio.

7. A semiconductor device having a p-channel MISFET and an n-channel MISFET each having a gate insulation film and a metal gate electrode above a semiconductive substrate, the gate insulation film being formed using a high dielectric constant film higher in dielectricity than a silicon oxide film, wherein
said metal gate electrode at a portion in contact with a surface of said gate insulation film of said n-channel MISFET is made of a metal silicide with its silicon amount greater than a stoichiometric composition ratio.

8. The device according to claim 7, wherein said metal silicide with its silicon amount greater than the stoichiometric composition ratio is made of a conductive material of at least one of a metal silicide selected from the group consisting of TiSiₓ, ZrSiₓ, HfSiₓ, VSiₓ, NbSiₓ, TaSiₓ, MoSiₓ, WSiₓ, NiSiₓ and CoSiₓ with a value of suffix “x” greater than two (2) and the group consisting of metal silicides of NiSiₓ with the value x being in excess of one (1).

9. The device according to claim 7, wherein said high dielectric constant film is made of at least one high dielectric constant film material selected from the group consisting of HfO₂, ZrO₂, HfSiOₓ, ZrSiOₓ, HfAlOₓ, ZrAlOₓ, Y₂O₃, and La₂O₃.

10. A method for making a semiconductor device having a p-channel MISFET and an n-channel MISFET each having a gate insulation film and a metal gate electrode above a semiconductive substrate, the gate insulation film being formed using a high dielectric constant film higher in dielectricity than a silicon oxide film, said method comprising:
forming a high dielectric constant film above said semiconductive substrate;
forming a first conductive film above said high dielectric constant film;
exposing said high dielectric constant film by removing a portion of said first conductive film in a region in which said p-channel MISFET is to be formed while leaving another portion of said first conductive film in a region used for formation of said n-channel MISFET; and
forming a second conductive film to cover an exposed portion of said high dielectric constant film, said second high dielectric constant film containing therein nitrogen greater in amount than that of said first conductive film, wherein said first conductive film is for use as part of the metal gate electrode of said n-channel MISFET whereas said second conductive film is for use as part of the metal gate electrode of said p-channel MISFET.

11. The method according to claim 10, wherein in said step of forming the second conductive film, said second conductive film is deposited by chemical vapor-phase growth using a nitrogen-containing raw gas above a surface of said high dielectric constant film to thereby dope nitrogen into said high dielectric constant film.

12. A method for making a semiconductor device having a p-channel MISFET and an n-channel MISFET each having a gate insulation film and a metal gate electrode above a semiconductive substrate, the gate insulation film being formed using a high dielectric constant film higher in dielectricity than a silicon oxide film, said method comprising:
forming a high dielectric constant film above said semiconductive substrate;
forming a first conductive film above said high dielectric constant film;
exposing said high dielectric constant film by removing a portion of said first conductive film in a region in which said p-channel MISFET is to be formed while leaving another portion of said first conductive film in a region used for formation of said n-channel MISFET;
nitriding the exposed part of said high dielectric constant film by a plasma nitridation technique; and
forming a second conductive film to cover said high dielectric constant film thus nitrided, wherein
said first conductive film is for use as part of the metal gate electrode of said n-channel MISFET whereas said second conductive film is for use as part of the metal gate electrode of said p-channel MISFET.

13. The method according to claim 12, wherein said second conductive film contains nitrogen greater in amount than that of said first conductive film.

14. A method for making a semiconductor device having a p-channel MISFET and an n-channel MISFET each having a gate insulation film and a metal gate electrode above a semiconductive substrate, the gate insulation film being formed using a high dielectric constant film higher in dielectricity than a silicon oxide film, said method comprising:
forming a high dielectric constant film above said semiconductive substrate;
forming above said high dielectric constant film a second conductive film containing nitrogen therein;
exposing said high dielectric constant film by removing a portion of said second conductive film in a region in which said n-channel MISFET is to be formed while leaving another portion of said second conductive film in a region used for formation of said p-channel MISFET; and
forming a first conductive film to cover the exposed part of said high dielectric constant film, said first conductive film being less in nitrogen content than said second conductive film,
wherein said first conductive film is for use as part of the metal gate electrode of said n-channel MISFET whereas said second conductive film is for use as part of the metal gate electrode of said p-channel MISFET.

15. The method according to claim 14, wherein in said step of forming the second conductive film, the nitrogen-containing second conductive film is formed while preventing nitrogen from being added to said high dielectric constant film.

16. The method according to claim 10, wherein said first conductive film is formed so that the amount of nitrogen as contained therein is substantially zero.

17. The method according to claim 10, further comprising:
forming an interface layer comprised of a silicon oxide film in a region sandwiched between said semiconductive substrate and said high dielectric constant film.

18. The method according to claim 16, further comprising:
forming an interface layer comprised of a silicon oxide film in a region sandwiched between said substrate and said high dielectric constant film.

19. A method for making a semiconductor device having a p-channel MISFET and an n-channel MISFET each having a gate insulation film and a metal gate electrode above a semiconductive substrate, the gate insulation film being formed using a high dielectric constant film higher in dielectricity than a silicon oxide film, wherein
said metal gate electrode at a portion in contact with a surface of said gate insulation film of said n-channel MISFET is made of a metal silicide with its silicon amount greater than a stoichiometric composition ratio whereas said high dielectric constant film is made of at least one kind of high dielectric constant film material as selected from the group consisting of HfO₂, ZrO₂, HfSiOₓ, ZrSiOₓ, HfAlOₓ, ZrAlOₓ, Y₂O₃, and La₂O₃.

20. The method according to claim 19, wherein said metal silicide is made of a conductive material of at least one of a metal silicide selected from the group consisting of TiSiₓ, ZrSiₓ, HfSiₓ, VSiₓ, NbSiₓ, TaSiₓ, MoSiₓ, WSiₓ, NiSiₓ and CoSiₓ with a value of x greater than 2 and the group consisting of metal silicides of NiSiₓ with the value x being in excess of 1.
